(19) United States
(12) Patent Application Publication
(10) Pub. No.: US 2008/0121268 A1
(43) Pub. Date: May 29, 2008

(54) PORTABLE POWER PACK

(76) Inventor: Anthony J. Pansini, Waco, TX (US)

Correspondence Address: NAMAN, HOWELL, SMITH & LEE, P.O. BOX 1470, WACO, TX, 76703, US

(21) Appl. No.: 11/564,521

(22) Filed: Nov. 29, 2006

(51) Int. Cl. H01L 31/042

(52) U.S. Cl. 136/246

(57) ABSTRACT

The present invention is directed toward an apparatus that generates electricity based on the phenomenon of rays from a source of radiation acting on a photovoltaic or similar material. In particular, the present invention provides a device for generating electricity from sources of radiation other than solar radiation in a portable form.

### BACKGROUND OF THE INVENTION

1. Field of the Invention

The present invention is directed toward an apparatus that generates electricity based on the phenomenon of rays from a source of radiation acting on a photovoltaic material. In particular, the present invention provides a device for generating electricity from sources of radiation other than solar radiation in a portable form.

2. Background Information

In this age of rising fuel costs and predictions of global warming associated with the use of fossil fuels, an increasing emphasis has been placed on developing alternative sources of energy. The list of possible electrical energy generation resources are wind, water, solar, and nuclear energy resources. One such resource, as has been studied since the nineteenth century, is that of solar power.

The conversion of sunlight or ultraviolet radiation into electricity has been well documented and is well understood by those skilled in the art. This conversion is accomplished by use of a photovoltaic cell. A typical photovoltaic cell consists of semiconductor material (usually silicon) having a junction of n-type silicon, doped with phosphorous, and p-type silicon, doped with boron. Solar radiation striking the cell raises the energy level of electrons and frees them from their atomic shells. The electric field at the p-n junction drives the electrons into the n-region, while positive charges are driven to the p-region. Typically, a metal grid, on the surface of the cell, collects the electrons, while a metal back plate collects the positive charges.

However, although the effect of solar radiation acting on photovoltaic material has been known and studied for over 150 years, significant obstacles are associated with the technology that prevents its widespread use. First, using solar energy to generate electricity by acting on a photovoltaic material is extremely inefficient. Furthermore, such photovoltaic modules produce electricity only when sunlight shines on them; thus, the energy output of the panels and storage capacity of batteries must be great enough to operate devices at night and on cloudy days when little sunlight is available. This, of course, results in extremely large, permanently mounted structures, requiring relatively large, clear areas for the sunlight. Finally, the mounting areas and the angles at which solar panels must be mounted are also critical in the generation of electricity from solar radiation acting on photovoltaic material.

In view of the limitations associated with the prior art, a substantial need exists for a power pack utilizing the photovoltaic effect but in a much more compact, portable form than the traditional photovoltaic panel. Applicant's invention, through a novel combination of component pieces and materials, provides such a power pack.

### SUMMARY OF THE INVENTION

The general purpose of the present invention, which will be described subsequently in greater detail, is to provide a portable power generating device, which contains many of the advantages of the prior art along with significant novel features that result in a power generating device that is not anticipated, rendered obvious, suggested, or even implied by any of the known devices, either alone or in combination.

In view of the foregoing, it is an object of the present invention to provide a device for generating electricity from a source of radiation acting on a photovoltaic material.

It is another object of the present invention to provide a device for generating electricity that does not rely on solar radiation.

It is another object of the present invention to provide a device for generating electricity that is compact.

It is another object of the present invention to provide a device for generating electricity that is portable.

It is another object of the present invention to provide a device for generating electricity that may function twenty-four hours a day.

It is another object of the present invention to provide a device for generating electricity that may function regardless of the weather.

In satisfaction of these and other related objectives, the present invention provides a device for generating electricity. The present invention provides a device that generates electricity based on the phenomenon of rays from a source of radiation acting on a photovoltaic material, such as compounds of silicon. Although reference to photovoltaic material is made throughout, it should be understood that the present invention also includes similarly acting or equivalent material that can be used for transforming waves of radiation into electrical energy as previously described. The electricity produced is direct current and its capacity depends on the intensity of the source of radiation, the activity of the photovoltaic material, and the duration of the activity.

An embodiment of the present invention, known as a roll or coil type, provides a radioactive material centered in a cylindrical or round, insulated, contamination-proof, sealed container. The radioactive material is surrounded by cylindrical coils of alternating layers of photovoltaic materials, conducting materials, and insulating materials. As the selected radioactive material emits waves of radiation, the combination of the photovoltaic material and the conducting material replicate the function of the typical photovoltaic cell, generating a direct current of electricity. A control system, which may be separate or integral to the unit itself, may be utilized to control the output, send the direct current to storage and/or to invert the direct current to usable alternating current for use in any number of areas or devices, currently energized by alternating electrical current.

An alternate embodiment of the present invention, known as a stack or pile type, provides a radioactive material at one end of a square, rectangular or other shaped, insulated, contamination-proof, sealed container. The radioactive material has access to multiple, alternating layers of photovoltaic materials, conducting materials, and insulating materials. Similar to the first embodiment, as the selected radioactive material emits waves of radiation, the combination of the photovoltaic material and the conducting material replicate the function of the typical photovoltaic cell, generating a direct current of electricity. Again, a control system, which may be separate or integral to the unit itself, may be utilized to send the direct current to storage and/or to invert the direct current to usable alternating current for used in any number of areas or devices, currently energized by alternating electrical current.

Applications of the present invention are near limitless. From a small unit powering a vacuum cleaner to a larger unit replacing the meter of a utility company in residential neighborhoods. Furthermore, the device of the present invention is envisioned to eventually replace engines powering motor vehicles, boats, and even airplanes. Finally, practice of the present invention is seen to possibly be most beneficial in developing countries where traditional energy infrastructure is presently lacking.

### BRIEF DESCRIPTION OF THE DRAWINGS

Applicant's invention may be further understood from a description of the accompanying drawings, wherein unless otherwise specified, like referenced numerals are intended to depict like components in the various views.

FIG. 1 is a cross-sectional view of the apparatus of the present invention.

FIG. 2 is a cross-sectional view of the embodiment in FIG. 1 along line 2-2.

FIG. 3 is a cross-sectional view of an alternate embodiment of the present invention.

FIG. 4 is a cross-sectional view of the embodiment in FIG. 3 along line 4-4.

### DETAILED DESCRIPTION OF THE PREFERRED EMBODIMENT

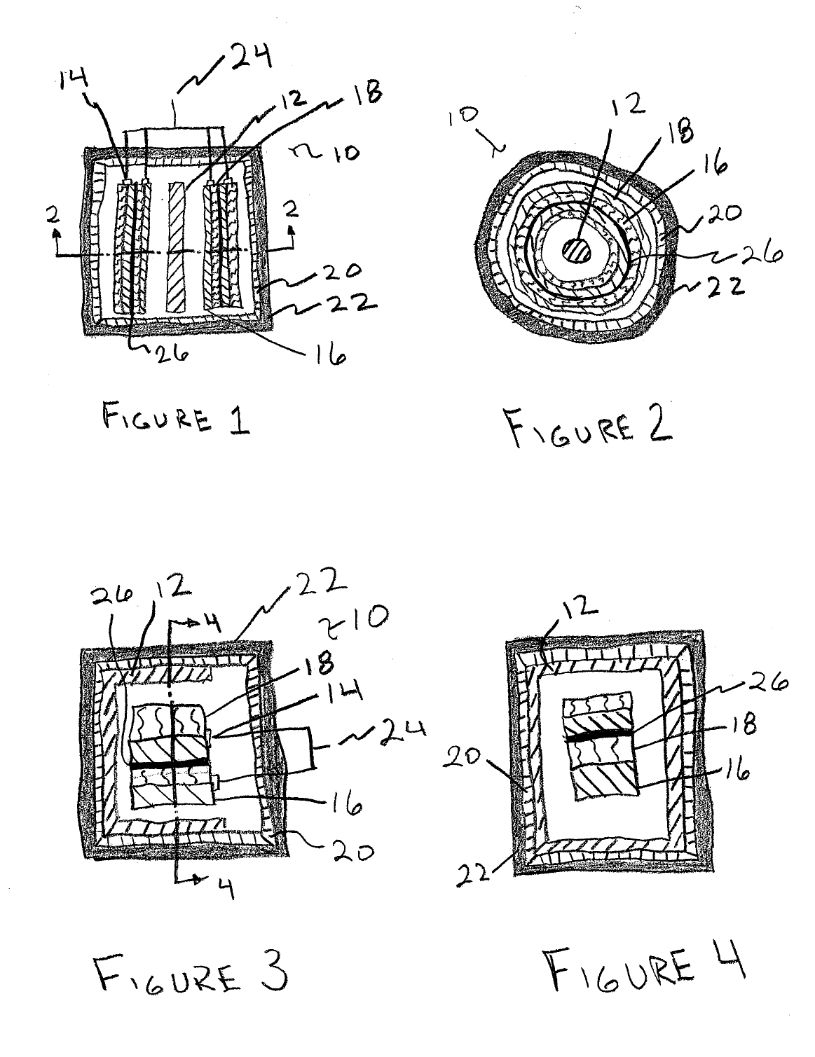

Referring to FIGS. 1 and 2, a device for generating electricity is shown and is generally designated by numeral 10. In a first embodiment, device (10) is comprised of a radiation source (12). In the preferred embodiment, radiation source (12) is a radioactive material as is known by one skilled in the art. Examples of such a radioactive material are radionuclides such as I-131, Tc-99, Co-60, Ir-192, Cs-137, polonium-210, tritium, americium, and thorium. The exact material comprising radiation source (12) is not as important as the requirement that the radiation waves exerted by radiation source (12) be of such a wavelength as to act upon photovoltaic material resulting in the most efficient generation of electricity.

Still referring to FIGS. 1 and 2, radiation source (12) is surrounded by multiple wraps of coil (14). As seen in FIG. 2, coil (14) is wrapped cylindrically around radiation source (12). Referring to FIG. 1, it is seen that coil (14) is made up of alternating layers of photovoltaic material (16), conducting material (18), and insulating material (26). Photovoltaic material (16) may be comprised of crystalline silicon or other photovoltaic materials as known in the art, including, but not limited to gallium arsenide (GaAs), amorphous silicon (a-Si), cadmium telluride (CdTe), or copper indium diselined (CuInSe₂ or CIS). Conductive material (18) may be copper or other suitable substitute as known in the art. Insulting material (26) may be rubber, glass, porcelain or other suitable substitute as known in the art.

Next, as seen in FIG. 2, insulating member (20) completely surrounds the cylindrical wraps of coil (14). Insulating member (20) is a material selected from those that are extremely poor conductors of electricity as known by those skilled in the art. Examples of insulating member (20) include, but are not limited to glass, porcelain or composite polymer materials. Fully surrounding, containing and sealing the components of device 10 is outer container (22). Container (22) must be of such material that is impenetrable by the waves of radiation emitted from radioactive material (12). An example of container (22) material is lead. Finally, as best seen in FIG. 1, control system (24) is shown. Control system (24) may be of various types and configurations as known in the art for collecting, storing, controlling, or transferring electrical energy generated from device (10). As such, control system (24) may be either integral or separate from device (10) as dictated by the application.

Now referring to FIGS. 3 and 4, an alternative embodiment of device (10) is shown. In this embodiment, container (22) is square or rectangular in shape as opposed to cylindrical, as shown in the first embodiment. Again, insulating member (20) completely lines container (22) as in the first embodiment. Radioactive material (12) is situated along the interior of insulating material (20). Additionally, instead of cylindrical coils of photovoltaic material (16), conducting material (18), and insulating material (26), each of the respective materials are situated in layers as shown in FIG. 3. Finally, control system (24) is shown as in the first embodiment as well.

In either embodiment, the function of the power pack device (10) is the same. As radioactive material (12) emits waves of radiation, the combination of photovoltaic material (16) and conducting material (18) replicate the function of the typical photovoltaic cell, generating a direct current of electricity. Control system (24), which may be separate or integral to unit (10) itself, may be utilized to send the direct current to storage and/or to invert the direct current to usable alternating current for use in any number of areas or devices, currently energized by alternating electrical current.

Finally, device (10) may be sized according to the desired application. It is envisioned that device (10) could be small enough to energize small household appliances or large enough to supply homes or buildings with all its electricity. Additionally, the power pack of the present invention could be used to power motor vehicles, boats, and airplanes. Finally, as previously noted, device (10) is anticipated to have its greatest effect on developing countries currently without any existing electrical power infrastructure.

Although the invention has been described with reference to specific embodiments, this description is not meant to be construed in a limited sense. Various modifications of the disclosed embodiments, as well as alternative embodiments of the inventions will become apparent to persons skilled in the art upon reference to the description of the invention. It is, therefore, contemplated that the appended claims will cover such modifications that fall within the scope of the invention.

I claim:

1. An apparatus for generating electricity, comprising:
a radiation source, said radiation source being a radioactive material;
a coil member, said coil member having alternating layers of a photovoltaic material, a conducting material, and an insulating material, said coil member surrounding said radiation source, said coil member being configured to act as a photovoltaic cell to generate direct current;
an insulating member, said insulating member completely surrounding said radiation source and said coil member; and
a container member, said container member being substantially impenetrable by said radiation source, said container member completely enclosing said radiation source, said coil member, and said insulating member.

2. The apparatus of claim 1 further comprising a control member, said control member being capable of collecting and diverting direct current.

3. The apparatus of claim 2 wherein said control member is capable of inverting direct current into alternating current.
